(19) United States
(12) Patent Application Publication
(10) Pub. No.: US 2026/0360999 A1
(43) Pub. Date: Nov. 12, 2026

(54) ELECTRICAL ELEMENT

(71) Applicant: GENTHERM GMBH, Odelzhausen (DE)

(72) Inventor: Dmytro Arvaj, Budapest (HU)

(21) Appl. No.: 19/119,209

(22) PCT Filed: Oct. 26, 2023
(86) PCT No.: PCT/IB2023/000669

§ 371 Date: Apr. 8, 2025

(30) Foreign Application Priority Data
Oct. 26, 2022 (DE) 10 2022 003 989.3
May 24, 2023 (DE) 10 2023 002 106.7
Jul. 9, 2023 (DE) 10 2023 002 790.1

(51) Int. Cl. H01R 4/02; H01G 2/02; H01R 43/02; H05B 3/00; H05K 9/00

(52) U.S. Cl. CPC H01R 4/023; H01G 2/02; H01R 43/0207; H05B 3/0019; H05K 9/0064; H01R 2201/26

(57) ABSTRACT

A sensor terminal module that includes at least two electric terminals; and a sensor; the sensor has at least two supply lines; a first supply line of the at least two supply lines is connected to a first electric terminal of the at least two electric terminals, and a second supply line of the at least two supply lines is connected to the second electric terminal of the at least two electric terminals; the sensor terminal module comprises at least one object or a carrier to which at least one of the at least two electric terminals and/or the sensor is connected by ultrasonic welding.

### CROSS REFERENCE TO RELATED APPLICATIONS

This application is a National Stage Entry of PCT/IB2023/000669 filed on Oct. 26, 2023, which claims priority to DE 10 2022 003 989.3 filed on Oct. 26, 2022; DE 10 2023 002 106.7 filed on May 24, 2023; and to DE 10 2023 002 790.1 filed on Jul. 9, 2023, the entireties of which are all incorporated by reference herein for all purposes.

### FIELD

The invention relates to an electrical element (hereinafter also referred to as functional element)according to the generic term of claim 1, an object according to the generic term of claim 10, a module according to the generic term of claim 12 and a method according to the generic term of claim 23.

### BACKGROUND

In the prior art, electrical elements are usually connected to objects by sewing, gluing with an adhesive, laminating or other complex and cost-intensive techniques. These conventional connection techniques for electrical elements are not only cost-intensive, but also delay the manufacturing process and can also result in both visible and tactile, and thus optical and haptic, undesirable deviations in the shape of the object to which the electrical element has been attached.

### SUMMARY

The underlying problem of the invention is thus to improve the connecting of an electrical element to an object.

The problem is solved with an electrical element of the type mentioned at the beginning, wherein the electrical element is adapted to be connected to the object by means of ultrasonic welding.

The fact that the electrical element can be connected to the object by means of ultrasonic welding means that manufacturing processes can be significantly accelerated compared to other conventional manufacturing techniques, such as sewing, gluing and/or laminating. For example, a manufacturing process for connecting an electrical element to an object using ultrasonic welding is up to four times faster than sewing or gluing. In addition, ultrasonic welding is an extremely precise manufacturing technique that leaves no visible or tactile marks on the electrical element and/or the object to which the electrical element is to be connected. In this way, reliable, precise, visually barely visible and haptically barely perceptible connections of electrical elements to objects can be realized quickly and cost-effectively.

Preferably, ultrasonic welding is carried out using an ultrasonic welding device. Preferably, the ultrasonic welding device comprises at least one sonotrode and/or at least one anvil and/or at least one workpiece receptacle for receiving the electrical element and/or the object. Ultrasonic welding makes it possible to weld elements and/or objects together with pinpoint accuracy by introducing ultrasonic waves with frequencies between 40 kHz and 70 kHz with an amplitude of 5 μm to 50 μm into the components to be welded in a spot and/or line shape, so that frictional heat is generated and the objects to be connected melt in a spot and/or line shape and, preferably under the effect of pressure, are consequently joined in a material-locking manner. Ultrasonic welding is a cost-saving and environmentally friendly joining technique, as no auxiliary materials such as adhesives are required and energy consumption is low. In addition, the precise control technology of ultrasonic welding equipment ensures consistent quality through accurate and reproducible results. As the start-up and waiting times for heating and cooling the tools and the objects to be joined together are extremely short, the objects can be connected to each other in fractions of a second, saving a considerable amount of time.

In a preferred embodiment of the electrical element, the electrical element is formed as a conductor strand or as a sensor element or as an electrical connection or as a shielding element against electromagnetic interference or as an electric heating device. A conductor strand can be an essentially one-dimensional, straight or curved elongated element. A conductor strand is preferably at least partially electrically conductive. The conductor strand is preferably formed as a resistance heating wire, a shielding strand, an antenna or a sensor strand.

In another preferred embodiment of the electrical element, the electrical element is adapted to be connected to a carrier element, in particular by means of ultrasonic welding, wherein the electrical element is preferably adapted to be connected to the carrier element in a layered pattern. The carrier element is preferably adapted to carry one or more electrical elements, in particular a surface heating device, a shielding device, a sensor device and/or an electric terminal. The carrier element is preferably formed as a flat layer of polymeric material, as the wall of an inflatable fluid-container, in particular a pneumatic bladder of a massage device and/or a vehicle seat, as the electrical layer of a shielding device, as the cover of a vehicle seat and/or another vehicle interior, or as a fleece or as a foil. The carrier element preferably has a thickness of between 0.1 mm and 3 mm, in particular a thickness of between 0.1 mm and 1 mm, especially preferably a thickness of between 0.1 mm and 0.6 mm, in particular if the carrier element is a flat layer. The carrier element preferably has a melting temperature above the temperatures that occur during ultrasonic welding, preferably above 200 °C, in particular above 250 °C, particularly preferably above 400 °C Preferably, the carrier element is adapted to carry electrical elements on multiple of its sides. If the carrier element is formed as a layered carrier element, it preferably carries electrical elements on both of its opposite surfaces, so that these electrical elements can be easily electrically insulated from each other, wherein a layered carrier element is a two-dimensional element, preferably even if it extends in a third dimension, for example due to a curvature. If a carrier element carries conductor strands on both its surfaces, the thickness of the carrier element is preferably at least 50% of the combined thickness of the two thickest strands on each of both surfaces. Depending on the penetration depth of such conductor strands into the carrier element during ultrasonic welding, it may be preferred to select a minimum thickness of the carrier element that is at least equal to the sum of the thickness of the thickest strand on one surface of the carrier element and the thickness of the thickest strand on the opposite surface of the carrier element. This prevents the carrier element from being damaged or even completely severed from one of the two sides during ultrasonic welding. Preferably, the carrier element consists at least partially of an electrically insulating material, for example polyurethane and/or of a stretchable material, wherein stretchable means that such a material allows the carrier element an extension of at least 5 to 15% without material damage, at least without significant damage. The stretchability of the material of the carrier element is particularly important if the carrier element is part of a vehicle steering wheel, in particular as a carrier element of a heating element, a shielding element or a capacitive sensor element.

Preferably, at least one conductor strand is attached to the carrier element in a layer pattern, wherein the pattern depends on the function of the conductor strand. To build up such a layer pattern, at least one strand is preferably at least partially arranged on the carrier element in a wave-like pattern, in particular in the form of a sine wave. Such a pattern enables the conductor strand to compensate for mechanical stresses and thus avoid damage. Sine wave patterns are particularly suitable for heating strands. The conductor strand can also be applied to the carrier element in a zig-zag pattern, wherein a zig-zag pattern comprises multiple straight line sections and/or multiple intermediate bends, for example of 90°, wherein preferably at least two strands are arranged in parallel in a straight line section and/or in the region of an intermediate bend. Preferably, the distance between two strands arranged in parallel is less than 5 mm, in particular less than 2 mm, especially preferably 1 mm or less. In particular, the arrangement of shielding strands ensures good shielding from electromagnetic influences by keeping the distance between the conductors as small as possible. In addition, at least one strand can be arranged in a U-shaped pattern on the carrier element with multiple straight line sections and/or with multiple intermediate bends of essentially 180°. Even with a U-shaped arrangement, distances of less than 1 mm between neighboring conductor strands are particularly preferred.

In a further preferred embodiment of the electrical element, the electrical element is formed as a monofil conductor strand or as a multifil conductor strand comprising multiple sub-strands, wherein the monofil and/or the multifil conductor strand comprises at least one, preferably at least two layers, preferably three layers, particularly preferably at least one electrically conductive wire and/or at least one protection layer and/or at least one melting layer. The electrically conductive wire is preferably formed as the electrically conductive core of the conductor strand. The electrically conductive core is preferably formed from metal, in particular from copper or a copper alloy or from steel or an iron alloy. Preferably, the protection layer at least partially surrounds the electrically conductive wire. Preferably, the melting layer at least partially surrounds the electrically conductive wire and/or the protection layer. Preferably, the electrical wire functions as a heating wire, sensor wire, antenna or shielding wire. In particular, the electric wire can act as a capacitive presence detector. The electrical wire can also serve as a shielding wire, in particular for shielding a presence detector from the influences of a heating device.

A multifil conductor strand preferably comprises multiple electrically conductive sub-strands or is composed of multiple electrically conductive sub-strands, wherein the sub-strands are preferably each formed as monofil conductor strands as described above. A multifil strand preferably comprises multiple electrically conductive wires and/or multiple protection layers and/or multiple melting layers. Preferably, a multifil strand comprises between 1 and 150, in particular between 2 and 8 conductive wires and/or protection layers and/or melting layers. Preferably, a multifil conductor comprises at least one conductive wire acting as a heating wire, at least one conductive wire acting as a sensor and/or at least one non-conductive carrier, in particular made of mineral fiber, preferably glass. Multifil conductor strands have the advantage that they increase adhesion to a carrier element compared to a monofil strand of a similar diameter, in particular if the multifil strand does not have an outer mantle. The at least one protection layer can serve to electrically insulate the conductive wire and/or fulfill mechanical functions, for example protecting the conductive wire from mechanical stress by absorbing tensile and/or bending forces, in particular during ultrasonic welding processes. The protection layer preferably consists at least partially of a polymeric material. The protection layer covers and/or at least partially surrounds the core.

The protection layer preferably has a melting temperature above 220 °C, preferably above 240 °C The protection layer has at least partially a thickness of less than 0.5 mm, in particular less than 0.1 mm, especially preferably less than 0.01 mm. The electrically conductive wire is preferably formed in such a way that bending radii of 1 mm are possible, for example with a wire diameter of less than 0.2 mm. Such an electrically conductive wire preferably has an electrical resistance of between 0.5Ω/m and 3Ω/m, in particular between 1 and 2Ω/m, especially preferably between 1.2Ω/m and 1.8Ω/m, in particular if the electrical wire is formed as a heating wire.

The melting layer can be formed as a fixation layer and/or as an additional insulation layer. The melting layer preferably at least partially covers the core and/or the protection layer. The melting layer is preferably formed from a polymeric material. The melting layer preferably has a lower melting temperature than the protection layer, preferably below 250 °C, in particular below 200 °C, wherein the melting temperature is at least 20 °C, preferably 50 °C lower than that of the protection layer. The melting layer preferably has a thickness of at least partially less than 0.5 mm, in particular less than 0.1 mm, especially preferably less than 0.01 mm. Preferably, the melting layer is used to be melted in a targeted manner during an ultrasonic welding process, wherein the melted melting layer is preferably brought into contact with a region of an object that has also been melted and a material-locking connection can be produced in this way by melting. In particular, these layers can be designed as a varnish.

In a further development of the electrical element, the sensor element is formed as a temperature sensor or pressure sensor or presence detector. A sensor element formed as a temperature sensor is adapted in particular to monitor the temperature of a heating element and/or a heating strand, wherein a temperature sensor is formed in particular as an NTC sensor or thermostat or thermistor. A pressure sensor is preferably adapted to monitor the pressure of an inflatable fluid-container. A presence detector (hands-on detection) is preferably adapted to detect a vehicle occupant, in particular the hands of a vehicle occupant, and/or movements of a vehicle occupant. A presence detector is preferably designed as a capacitive sensor, which comprises a capacitor plate formed as a textile or foil for capturing a change in capacitance in the vicinity of the sensor. The sensor element is preferably part of a sensor device, in particular a sensor device for temperature monitoring and/or for displaying certain temperature thresholds. A sensor device preferably comprises at least one sensor and at least one supply line which supplies the sensor with energy and/or with signals and/or which forwards data from the sensor to a control unit, wherein the control unit can be, for example, the vehicle control unit (ECU) or can be part of the object by means of which the sensor is connected. Preferably, the sensor device comprises at least one sensor with two supply lines connecting the sensor to two electrical potentials different from each other, wherein the sensor and the two supply lines are part of an electrical circuit, the sensor being a switching device which regulates an electrical flow through this circuit.

Furthermore, an electrical element according to the invention is particularly preferred, wherein the electric terminal is formed as an electrically conductive base, in particular as a metal plate and/or as a section of an electrically conductive foil, wherein the electric terminal is adapted to be connected to an electrical device. The electrically conductive base is preferably formed in a rectangular or square shape. The electrically conductive base is preferably connected to an internal electrical element of an electrical device, for example to an internal conductor strand of a heating device, a sensor device or a shielding device. The electrically conductive base is preferably connected with an external electrical conductor to an external power source, wherein the external power source is arranged at a distance from the electrical device. The electric terminal is preferably formed at least 50% from copper and/or at least 50% from iron and/or at least 50% from the material of a connected internal conductor strand and/or at least 50% from the material of a connected external conductor strand, wherein the internal and/or the external conductor strand and/or the electric terminal preferably consist of at least 80%, in particular at least 95%, of copper. Preferably, the electric terminal can be connected to the internal conductor strand of the electrical device and/or to the external conductor strand of the power source by means of soldering and/or resistance welding.

It is further advantageous to provide an electrical element according to the invention, in which the electrical shielding element comprises at least one carrier element and at least one shielding strand. Preferably, the shielding strand is formed as an electrical conductor. Preferably, the shielding device is adapted to reduce or completely cancel the effect of electromagnetic influences, in particular if it is arranged between a heating device and a sensor device. Preferably, the shielding device is part of a multi-layer sandwich structure consisting of a heating device for heating the hands of a driver of a vehicle, a sensor device for monitoring the driver's hands and a shielding device for decoupling the heating device from the sensor device to avoid electromagnetic effects. Preferably, the shielding device comprises a carrier element according to claim 3 and/or a conductor strand according to claim 4. Preferably, the carrier element and the shielding strand are connected to each other by ultrasonic welding. Preferably, the shielding strand is connected to the carrier element without stitches and/or seams. The carrier element can carry the shielding strand together with a sensor strand and/or a heating strand. Preferably, the shielding strand, the sensor strand and/or the heating strand are attached to opposite surfaces of the carrier element and/or embedded from opposite sides of the carrier element, and/or the different strands follow a different layer pattern from each other and/or the strands maintain a minimum distance from each other, wherein the distance is sufficient to insulate them electrically from each other, wherein the sum of the thickness of the strands is less than the thickness of the common carrier element.

In another preferred embodiment of the electrical element according to the invention, the electric heating device comprises at least one carrier element, at least one electric heating resistor and at least one electric heating strand. Preferably, the electric heating device is adapted to heat a surface of an object in a vehicle interior, in particular an armature, a vehicle door, an armrest, a pillow or a cushion of a vehicle seat or a steering wheel, a battery heating device, a patient heating device, in particular a disposable one-way heating blanket. Preferably, the heating resistor and/or the heating strand is attached to the carrier element free of textile stitches and free of seams, in particular by means of ultrasonic welding. The heating strand is preferably connected to the carrier element at least in sections. The heating device preferably comprises at least one heating strand, which is attached to a carrier element formed as a foil carrier, which can be attached to an object to be heated. The heating device preferably comprises at least one heating strand, which is attached to a carrier element formed as a foil carrier, which can be or is attached to a cover of an object to be heated, wherein the heating device is preferably arranged between the object and its cover, in particular when the diameter of the heating strand is smaller than the thickness of the carrier element, so that a heated object can be produced efficiently and without damaging its surface.

The heating device preferably comprises at least one heating strand which is attached directly to a cover of an object, wherein the heating device is preferably arranged between the object and its cover, so that the thinnest possible heating strands can be used, which enable operation of the heating device with the lowest possible energy losses. The heating device preferably comprises at least one heating strand, which is attached to the surface of an object to be heated. The heating device preferably comprises at least one heating strand which is attached to an object by at least partially embedding the heating strand in the surface of the object, so that plastic parts with embedded strands can be produced, for example steering wheels, door panels or side cushions of headrests, in particular if such objects consist at least partially of a polymeric material, in particular a thermoplastic material, wherein such an object preferably has at least one attachment zone which can be welded to the heating strand by means of ultrasonic welding. Preferably, the heating strand is formed as a multifil heating strand, wherein at least one of these multifil heating strands has at least two, preferably three, layers.

Preferably, the heating device comprises at least one sensor terminal module and/or a connection area for connecting to an electrical voltage source. Preferably, the heating strand is applied directly to a heatable cover, in particular without intermediate layers, for example of cushioning material. Preferably, the heating strand is at least partially formed from a metal. Preferably, a monofil heating strand has a diameter of less than 1 mm, in particular less than 0.1 mm, especially preferably less than 0.01 mm. Preferably, a heating strand and a carrier element together form a heating layer, wherein the carrier element is preferably formed from an insulation material with a thickness of at least 0.7 mm and the heating strand is preferably a maximum of 0.2 mm thick and is embedded in the carrier element.

In a further preferred embodiment of the electrical element according to the invention, at least two electric terminals and at least one sensor together form an electrical element formed as a sensor terminal module, wherein the sensor of the sensor terminal module preferably has at least two electric supply lines and the first supply line is connected to the first electric terminal and the second supply line is connected to the second electric terminal. Preferably, the sensor terminal module is sealed for protection against external influences, for example against moisture; in particular, the sensor terminal module is welded between two carrier elements, for example between two foils, by means of ultrasonic welding. Preferably, the sensor terminal module is adapted to be connected to heating devices, shielding devices and/or sensor devices. Preferably, at least one supply line and one electric terminal form an integral part comprising at least one conductive plate, at least one foil and/or at least one film. Preferably, the sensor terminal module is connected to a carrier element, in particular to a carrier element of a heating device, a shielding device or a sensor device. A sensor terminal module can be used to reduce the number of parts and the number of assembly steps. The sensor terminal module can comprise at least three electric terminals. The sensor terminal module can further comprise at least two ends of electrical strands for connecting another electrical element instead of a sensor to an external voltage source, wherein the first of these ends can be connected to one of the first and second electric terminals and/or the second end can be connected to the third terminal, so that two different electrical elements, for example a sensor and a heating device, can be operated independently of each other. Such an end of a conductor strand can be, for example, the end of a heating strand, a grounding line, a shielding device and/or a connection line of a capacitor layer of a capacitive sensor. Preferably, the ends of the conductor strand are the ends of the same heating strand and a grounding line of an electromagnetic shielding device and a connecting line of a capacitor layer of a capacitive sensor. In this way, the space required for a connection area can be significantly reduced, for example from around 60 mm×100 mm to around 30 mm×30 mm for a surface heating device with conventional crimping of the heating strands instead of ultrasonic welding.

Preferably, the sensor terminal module comprises a terminal carrier in addition to a carrier element of another electrical element, so that assembly is simplified if there are more than two electric terminals. Preferably, the sensor terminal module comprises at least one conductor strand. Preferably, the sensor terminal module comprises a sensor device for monitoring at least one electrical element and/or the at least one conductor strand. Preferably, the sensor device monitors a supply line that connects the sensor to the electric terminal and which, together with the conductor strand, is both electrically and mechanically connected to the same electric terminal, so that precise measurements are possible due to the proximity of the sensor to the conductor strand. Preferably, the sensor is arranged at a distance of less than 2 cm from the conductor strand, in particular less than 5 cm, especially preferably less than 2 mm. The conductor strand preferably forms at least one loop-shaped section, which surrounds the sensor at least in sections. Preferably, the sensor device comprises a guiding device for guiding a section of the conductor strand at least partly around the sensor in a defined manner, wherein the guiding device forms at least a section of a circle, in particular a semi-circle. Preferably, the sensor device comprises at least one sensor arranged in the center of such a formed circular section, wherein this arrangement enables a measurement that is precise due to the proximity to the sensor, but still allows stable control due to a still sufficient distance.

The problem underlying the invention is further solved by an object of the type mentioned at the beginning, wherein the electrical element is connected to the object by means of ultrasonic welding. Preferably, the electrical element is formed according to one of the above embodiments. For further advantages and modifications of the object according to the invention, reference is thus made to the advantages and modifications of the electrical element according to the invention.

In a preferred embodiment of the object according to the invention, the object is formed as a vehicle interior component or heatable vehicle component or steering wheel or inflatable fluid-container or vehicle seat component. A vehicle interior component is preferably formed as an armature, an armrest, a door cover or a vehicle roof. An inflatable fluid-container is preferably formed as a bladder, wherein the bladder can preferably be filled with air. A vehicle seat component is preferably formed as a seat cover, as a headrest or as a head side rest or as a seat side bolster.

The problem underlying the invention is further solved by a module of the type mentioned at the beginning, wherein the electrical element and the object of the module are connected to each other by means of ultrasonic welding. Preferably, the electrical element is formed according to one of the above embodiments. Preferably, the object is formed according to one of the above embodiments. With regard to the advantages and modifications of the module according to the invention, reference is thus made to the advantages and modifications of the electrical element and/or the object. A dynamic function is preferably a function of the module that requires the module to actively influence any operating parameters, in particular fluid flows and/or electrical currents.

In a preferred embodiment of the module according to the invention, the module is formed as a detection module for detecting heating energy on a steering wheel or detection module for detecting heating energy on a vehicle cover or heater contouring module for a vehicle seat or heater massage module for a vehicle seat or inflatable fluid-container with integrated heating device or sealed electric connection area or sensor terminal module.

In another preferred embodiment of the module according to the invention, at least one of the dynamic functions of the module is heating a person or detecting the presence of a person or massaging a person or adjusting the contour of a body supporting device or adjusting the volume of an inflatable fluid-container. Preferably, the person being warmed and/or detected and/or massaged is an occupant of a vehicle, in particular the driver of the vehicle. The body supporting device can, for example, be formed as a spinal support for the vehicle occupant.

In a further preferred embodiment of the module according to the invention, the module is formed as a presence detector module, in particular for detecting the presence and/or for detecting the movement of a human body part. Preferably, the presence detector module comprises a sensor for detecting changes in an electric field, wherein the field can also be a magnetic field. Preferably, the presence detector module comprises a sensor strand which detects changes in an electromagnetic field in the surroundings of the sensor strand, in particular changes caused by the presence of water in body parts of a vehicle occupant, and/or which detects changes in pressure in the surroundings of the sensor strand, in particular changes caused by the weight of the monitored body part. Preferably, the presence detector module comprises at least one carrier element, in particular a carrier element according to claim 3. Preferably, the sensor strand of the presence detector module is formed according to claim 4. Preferably, the sensor strand and the carrier element are joined together as described in claim 3, in particular by means of ultrasonic welding and/or without stitches and without seams. The carrier element of the presence detector module can also carry a shielding strand and/or a heating strand. The presence detector module can be substantially constructed as a shielding device according to claim 7.

In a further development of the module according to the invention, a module formed as a detection module for detecting heating energy on a steering wheel and/or a module formed as a detection module for detecting heating energy on a vehicle cover comprises at least one sensor device and/or at least one heating device and/or at least one shielding device, wherein multiple of these devices preferably together form a sandwich structure. Preferably, a detection module for detecting heating energy comprises at least one conductor strand which has a thickness of between 0.05 mm and 1.5 mm, in particular between 0.1 mm and 0.5 mm, particularly preferably between 0.1 mm and 3 mm, wherein the conductor strand is preferably formed as a heating strand or as a sensor strand or as a shielding strand. Preferably, the conductor strand is formed as a multifil strand with preferably 1 to 10 filaments for a sensor strand, 1 to 3 filaments for a shielding strand and/or 1 to 100 filaments for a heating strand. A detection module for detecting heating energy on a steering wheel preferably has a stretchability of between at least 5% and 15% without affecting, in particular without damaging, electrical elements or neighboring modules.

A detection module for detecting heating energy can be installed in a door cover, armrest or headrest of a vehicle. A detection module for detecting heating energy preferably comprises a carrier element formed as a heating carrier element, which is preferably formed from an insulation material with a thickness of at least 0.7 mm, and a heating strand attached to the heating carrier element and/or embedded in this heating carrier element, which preferably has a thickness of less than 0.2 mm. A detection module for detecting heating energy preferably comprises a sensor carrier element, which is preferably formed from an insulation material with a thickness of less than 0.7 mm, and a sensor strand attached to the sensor carrier element or embedded in the sensor carrier element, which has a thickness of less than 0.2 mm in diameter. A detection module for detecting heating energy preferably also comprises a shielding carrier element, which is preferably formed from an insulation material with a thickness of at least 0.7 mm and comprises a shielding strand attached to the shielding carrier element or embedded in the shielding carrier element, which preferably comprises a thickness of less than 0.2 mm. Preferably, the detection module for detecting heating energy comprises a combined heating shielding carrier element with a heating strand and a shielding strand, wherein the heating strand and the shielding strand are each attached to opposite surfaces of the combined carrier element and/or a combined sensor shielding carrier element with a sensor strand and a shielding strand, which are each attached to opposite surfaces of the combined carrier element.

Furthermore, a module according to the invention is particularly preferred, in which the module is formed as a device for adjusting the seat contour of a vehicle seat. The device can be used to dynamically adapt the contour of a vehicle seat to different situations. In particular, a vehicle seat can be adapted to the anatomy of a specific vehicle occupant, for example the driver. For example, the device can adjust the vehicle seat depending on driving maneuvers, in particular depending on curve-driving. The device can ensure that a vehicle occupant is not permanently seated in the same position to safeguard their health. The seat adjustment can also react to fatigue or imminent vehicle collisions, for example, to protect the driver. The device can be used to massage a vehicle occupant, in particular with increased temperature and/or increased pressure. Preferably, the device comprises at least one, in particular multiple, inflatable fluid-containers by means of which the contour of the seat can be individually adjusted.

A module according to the invention is further advantageous, in which the module is formed as an inflatable fluid-container and/or comprises at least one, preferably multiple inflatable fluid-containers, wherein preferably at least one conductor strand can be connected to the one or the multiple fluid-containers, in particular by means of ultrasonic welding, and/or wherein the at least one or multiple inflatable fluid-containers preferably comprises at least one sensor terminal module welded and/or sealed by means of ultrasonic welding. Preferably, the inflatable fluid-container is formed as a pneumatic bladder which can be filled with a gas, preferably with air, wherein the bladder preferably has a heating strand welded to the bladder, in particular on the inside of the bladder, and wherein the pneumatic bladder preferably comprises a sensor terminal module which is welded between two layers of the bladder in order to protect the sensor terminal module from external influences. In particular, at least one conductor strand is welded to the inside of the fluid-container.

Preferably, the fluid-container can be filled with a fluid, in particular with air, and can thus be inflated. Preferably, the fluid container is filled with a defined amount of air during certain operating phases, for example during curve-driving or another driving maneuver of a vehicle. The inflatable fluid-container preferably has at least one flexible wall which is impermeable to the fluid to be filled in, so that the shape and/or the contour of the wall of the fluid container and/or the entire fluid-container can be individually adapted by changing the quantity of fluid in the fluid-container. The wall of the fluid-container consists at least in part of a material that is not damaged by ultrasonic welding. Preferably, such a wall consists of a polymeric material, preferably polyurethane. Preferably, such a wall has a melting temperature which is higher than the melting temperature of at least one layer of a conductor strand attached to the wall, wherein the melting temperature of at least one wall is preferably around 20 °C, particularly preferably at least 50 °C higher than that of the conductor strand.

The wall of such a fluid-container preferably has a thickness which is greater than the thickness of one or multiple conductor strands connected to the fluid-container. Preferably, the wall has a thickness of between 0.1 mm and 5 mm, in particular between 0.1 mm and 2 mm, particularly preferably between 1 mm and 2 mm. The inflatable fluid-container is preferably formed as a fluid bladder, in particular as an air bladder. The inflatable fluid-container is preferably produced by welding at least two layers of a flexible wall material to the edges of the flexible wall material. Preferably, these layers have a similar size. Preferably, a gas-fillable, in particular an air-fillable bladder is created by welding the two layers together. Preferably, the fluid-container comprises one or multiple electrical elements, in particular one or multiple electrical elements as described above, and/or one or multiple electrical elements can be connected to the fluid-container, in particular by means of ultrasonic welding.

In particular, the fluid-container can comprise an electric heating element, a temperature sensor for monitoring the temperature of the heating element, a temperature sensor for monitoring the temperature of a vehicle occupant, a pressure sensor for monitoring the pressure within the inflatable fluid-container, a presence detector for detecting human body parts and/or a shielding device for shielding electromagnetic influences, in particular influences of the heating device in the direction of a vehicle occupant or in the direction of a presence detector. Preferably, these electrical elements, in particular a pressure sensor and/or a temperature sensor, for example an NTC sensor, are integrated on the fluid-container and/or in the fluid-container, in particular welded to the fluid-container by means of ultrasonic welding and/or embedded in the fluid-container. It is also preferred to combine an inflatable fluid-container with a heating device to realize a combined seat contour and/or seat temperature adjustment device which increases the comfort of a vehicle seat by providing a massage function, a seat contouring function and a heating function at the same time. A device for adjusting the seat contour of a vehicle seat preferably has at least one feature already described above for an inflatable fluid-container.

In another preferred embodiment of the module according to the invention, the module is formed as an inflatable fluid-container with an integrated heating device, wherein multiple inflatable fluid-containers and at least one heating device together preferably form a combined heating-massage module and/or a combined heating-contouring module for vehicle seats. Preferably, at least one of the multiple fluid-containers has a heating strand welded to the fluid-container by means of ultrasonic welding, wherein the heating strand is connected, in particular welded, to the layer of the fluid-container, in particular on the inside of at least one layer of the fluid-container. Preferably, at least one of the fluid-containers comprises a sealed sensor terminal module. An inflatable fluid-container with integrated heating device preferably has at least one heating strand integrated, preferably welded, into a flexible wall of the fluid-container, which heating strand is preferably embedded on the inside of a flexible wall, wherein the flexible wall with embedded heating strand is installed in a vehicle facing a vehicle occupant in order to warm the occupant. The integrated heating device can comprise a heating strand and a separate carrier element. The heating device can comprise, for example, a plastic multifilament, a fleece carrier and/or a heating strand made of steel or copper, wherein the heating strand can be sewn onto any flexible and/or flat carrier element. If the heating strand is attached to a separate carrier element, in particular sewn, this separate carrier element can be laminated onto the flexible wall of the fluid-container.

However, a copper heating strand formed as an electrical multifil strand is particularly preferred, which is attached directly to the wall of the fluid-container by ultrasonic welding, without a separate carrier element, and/or which is embedded in the wall of the fluid-container from the inside of the fluid-container. An arrangement of the heating strand inside the fluid-container protects the heating strand from mechanical stresses, in particular from shearing movements outside the fluid-container. If the heating device is attached to the fluid-container from the outside, it can, for example, be laminated to the outside of the fluid-container with a separate carrier element as described above. However, the service life can be considerably increased if the heating strand is attached directly to the wall of the fluid-container or is at least partially embedded in the wall of the fluid-container by ultrasonic welding. By integrating a heating function into fluid-containers, combined heating-massage modules and/or combined heating-contouring modules for vehicle seats can be realized.

In a further preferred embodiment of the module according to the invention, the module is formed as an electric connection area, which is preferably sealed from external influences by welding two protection layers by means of ultrasonic welding. A sealed electric connection area preferably comprises an electric terminal or an electric sensor terminal module as already described above. Preferably, the electric connection area is used to make electrical contact with at least one occupant detection device, a heating device, a sensor device, in particular for detecting pressure or temperature and/or a shielding device. The electric connection area is preferably arranged between the welded layers. At least one of the layers can be a carrier element of an electric element, which is connected to an external voltage source or, for example, an external control device via such a connection area.

At least one of the protection layers can also be a separate protection layer made of a suitable, preferably sealable material. At least one of the protection layers can also consist of at least part of a wall of a fluid-container. Preferably, the sealed electric connection area completely seals at least one electric terminal, preferably an entire connection module, so that time-consuming gluing or coating of contact surfaces or even shrink tubing is not required. When a fluid-container is provided with a sealed electric connection area, the two protection layers are preferably extensions of the turn of the fluid-container, preferably of an upper and a lower wall of the fluid-container. Preferably, electric terminals and/or sensors are sealed between these two layers. If a fluid-container is provided with a sensor terminal module and/or a sealed electric connection area, preferably at least the sensor of such a sensor terminal module is arranged inside the fluid-container, while a connection area of such a sensor terminal module is enclosed in the sealed electric connection area. This enables precise measurement and very simple installation. Such an arrangement is advantageous in particular if the fluid-container comprises a heating device and/or a temperature sensor and/or a pressure sensor and/or a presence detector within the fluid-container.

In a further development of the module according to the invention, the module is formed as a massaging device, which is preferably formed by welding two protection layers by means of ultrasonic welding. A massage device can be a massage device in general, which does not necessarily have to be related to a vehicle. A massage device can also be suitable for beds, massage tables, operating tables or reclining chairs, for example. A massage device can comprise any module and/or electrical element described above, in particular one or multiple fluid-containers with or without heating device and/or integrated sealed electric connection area, sensors and others, in particular a seat contouring device.

A module according to the invention is further preferred, wherein the module is a combined heating detection module, in particular for a steering wheel for heating and detecting the hands of a driver, wherein the heating detection module preferably comprises at least one heating strand, at least one sensor strand and/or at least one shielding strand, which are welded by means of ultrasonic welding on one carrier element together or on multiple carrier elements separately from each other.

The problem underlying the invention is further solved by a method of the type mentioned at the beginning, wherein the electrical element and the object are joined together by means of ultrasonic welding and/or soldering and/or thermal welding, in particular thermal compression welding. Preferably, in the method according to the invention, at least one electrical element according to one of the preceding embodiments is welded to at least one object according to one of the preceding embodiments to form a module according to one of the preceding embodiments. With regard to the advantages and modifications of the method according to the invention, reference is thus made to the advantages and modifications of the electrical element according to the invention, the object according to the invention and the module according to the invention.

Ultrasonic welding is understood to mean connecting by exposing at least one object to be connected to pressure and/or vibration in a frequency range of ultrasonic sounds. A connection by ultrasonic welding enables good attachment between an electrical element, in particular a conductor strand, and a carrier substrate, in particular a flat carrier element. This fixation is particularly strong due to the formation of a material-locking connection, in particular a bond, when the coating of a conductor strand, for example a melting layer strand, and the carrier material of the carrier element melt together as a result of ultrasonic welding. Soldering means attaching by adding molten material, wherein the added material contains, for example, an electrically conductive material and/or a material consisting of at least 50% tin, lead and/or another metal and/or an alloy with a melting temperature of below 500 °C, preferably with a melting temperature of below 300 °C. Preferably, the melting temperature of the soldering material is higher than the melting temperature of the components to be connected, so that the components to be connected are not damaged during joining. Thermal welding means attaching by melting material, wherein the material is preferably a constituent of at least one of the components to be connected to each other and/or an additionally added material containing at least 50% iron, aluminum and/or another metal and/or an electrically conductive alloy with a melting temperature above 250 °C.

### BRIEF DESCRIPTION OF THE DRAWINGS

In the following, preferred embodiments of the invention are explained and described in more detail with reference to the accompanying drawings. The Figures show:

FIG. 1 shows a schematic cross section of a conductor strand formed as a multifil electrical element;

FIG. 2a shows a top view of a conductor strand in a layer pattern on a carrier element;

FIG. 2b shows a top view of a conductor strand in a different layer pattern on a carrier element;

FIG. 3 shows a top view of a module formed as a sensor terminal module;

FIG. 4 shows a top view of a module formed as a connection area;

FIG. 5 shows a top view of a sensor terminal module connected to a conductor strand on a carrier element;

FIG. 6 shows a perspective view of a device for adjusting the seat contour of a vehicle seat with multiple fluid-containers;

FIG. 7 shows a top view of a welded sensor terminal module with welded connection area on a fluid-container with integrated conductor strand; and

FIG. 8 shows a perspective view of an inflated fluid-container with integrated heating device.

### DETAILED DESCRIPTION

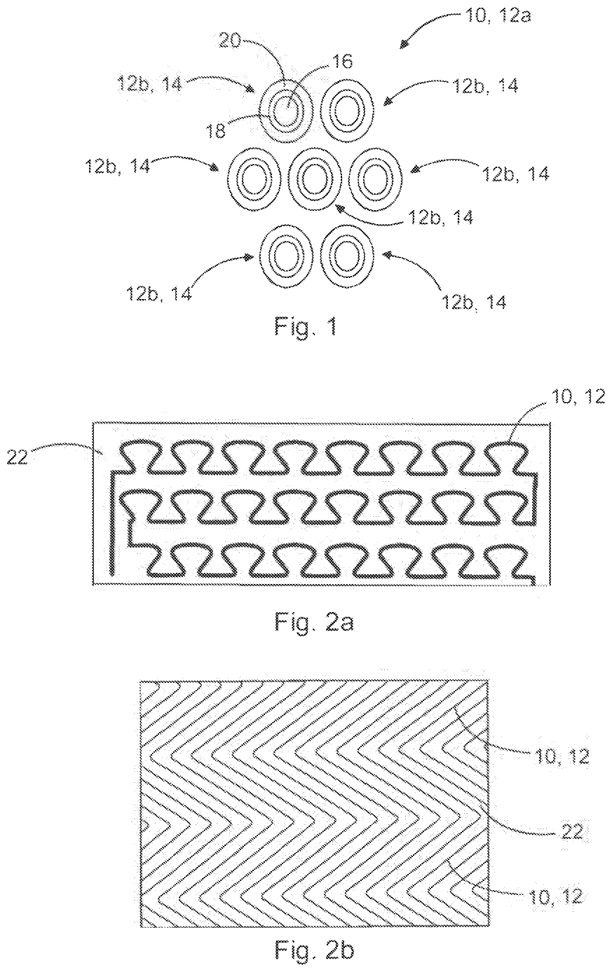

FIG. 1 shows an electrical functional element 10, which is formed as a multifil conductor strand 12a. The multifil conductor strand 12a comprises seven sub-strands 14, wherein the sub-strands 14 are each formed as monofil conductor strands 12b. Each monofil conductor strand 12b, which together form the multifil conductor strand 12a, comprises three layers, wherein each monofil conductor strand 12b comprises an electrically conductive wire 16, a protection layer 18 and a melting layer 20. The electrically conductive wire 16 forms the core of each monofil conductor strand 12b. The electrically conductive wire 16 is completely surrounded by the protection layer 18, wherein the protection layer 18 is formed as an insulating layer for insulating the wire 16, in particular for insulating the wire 16 from electrical influences. In addition, the protection layer 18 can protect the wire 16 from mechanical damage. The wire 16 and the protection layer 18 surrounding the wire 16 are in turn completely enclosed by the melting layer 20. The melting layer 20 is adapted to be selectively melted by means of a heat supply, in particular by ultrasonic welding, so that one, multiple or all of the monofil strands 12b and/or the multifil strand 12a can be attached in a material-locking manner to a carrier element 22 and/or to an object 100 by melting with the carrier element 22 and/or by melting with the object 100.

Preferably, the melting temperature of the melting layer 20 is below the melting temperature of the protection layer 18, so that during ultrasonic welding only the melting layer 20 is melted to attach the conductor strand 12a, 12b, but the protection layer 18 remains undamaged. The electrically conductive wire 16 can, for example, be formed from copper, a copper alloy, steel or another ferrous alloy. One, multiple or all of the monofil conductors 12b and/or the monofil conductor strand 12a are adapted to function as an electrically conductive wire, for example for a heating device, for a sensor device, as an antenna, for a shielding device, in particular as a heating wire, as a sensor wire, and/or as a shielding wire.

FIGS. 2a and 2b each show an electrical functional element 10 formed as a conductor strand 12, which is attached to a carrier element 22 in different layer patterns. The conductor strand 12 can be formed as a monofil conductor strand 12b or as a multifil conductor strand 12a. In particular, the conductor strand 12 can, for example, be formed as a heating strand for a heating device, as a sensor strand for a sensor device, as a shielding strand for a shielding device and/or together with the carrier element 22 form a heating device, a sensor device or a shielding device. Preferably, multiple conductor strands 12 attached to a carrier element 22 can be combined, in particular to form a combined heater-sensor device, heater-sensor-shielding device or sensor-shielding device, for example in that multiple carrier elements 22 each form a sandwich structure with at least one conductor strand 12. In addition, multiple conductor strands 12 can be arranged adjacent to and spaced apart from each other on a common carrier element 22, wherein at least one of the multiple conductor strands 12 is formed as a heating strand, another conductor strand 12 is formed as a sensor strand and/or another conductor strand 12 is formed as a shielding strand. For example, a heating strand can be adapted to warm a vehicle occupant. A sensor strand can be adapted to detect the presence of a vehicle occupant and/or to detect the heating energy of the heating strand. A shielding strand is adapted to shield interference from the heating strand to the sensor strand, in particular to shield electromagnetic interference from the sensor strand, in order to allow the heating energy to be monitored and/or the presence of a vehicle occupant to be detected without interference.

The carrier element 22 is preferably formed as a flat and/or planar carrier element 22. In particular, the carrier element 22 is formed as a foil or fleece. Preferably, the carrier element 22 is adapted to carry at least one conductor strand 12 on both of its opposite surfaces. Preferably, the carrier element 22 is adapted so that on at least one of its surfaces at least one conductor strand 12 can be connected, in particular welded and/or melted, in a material-locking manner to the carrier element 22 by means of ultrasonic welding. Preferably, the carrier element 22 is formed in such a way that it is not damaged during ultrasonic welding for attaching at least one electrically conductive conductor strand 12, in particular by selecting a suitable thickness of the carrier element 22. For example, the carrier element 22 can be at least 50% thicker than the sum of the two thickest conductor strands 12 to be attached to the carrier element 22 by ultrasonic welding, in particular when electrical conductors 12 are attached to both surfaces of the carrier element 22. The carrier element 22 is preferably formed from an electrically insulating material, in particular polyurethane.

FIG. 2a shows a conductor strand 12 fixed to a carrier element 22, which is arranged in a layer pattern, wherein the conductor strand 12 has multiple loops arranged side by side with straight sections and curved sections to form the layer pattern and wherein multiple loops of the conductor strand 12 arranged side by side form a row of loops, wherein multiple rows of loops are arranged at a distance from each other and adjacent to each other. FIG. 2b shows another layer pattern of one or multiple electrically conductive strands 12 attached to a carrier element 22. The one or more conductor strands 12 are formed in FIG. 2b in a zig-zag pattern with multiple straight line sections and multiple bends connecting the straight line sections, wherein multiple conductor strands 12 and/or multiple sections of one conductor strand 12 run adjacent to and spaced apart from each other in parallel. The layer pattern is preferably selected so that adjacent conductor strands 12, in particular a heating strand and a sensor strand, influence and/or interfere with each other as little as possible. In particular, a distance between two adjacent strands 12 is selected which minimizes mutual interference and/or disturbance.

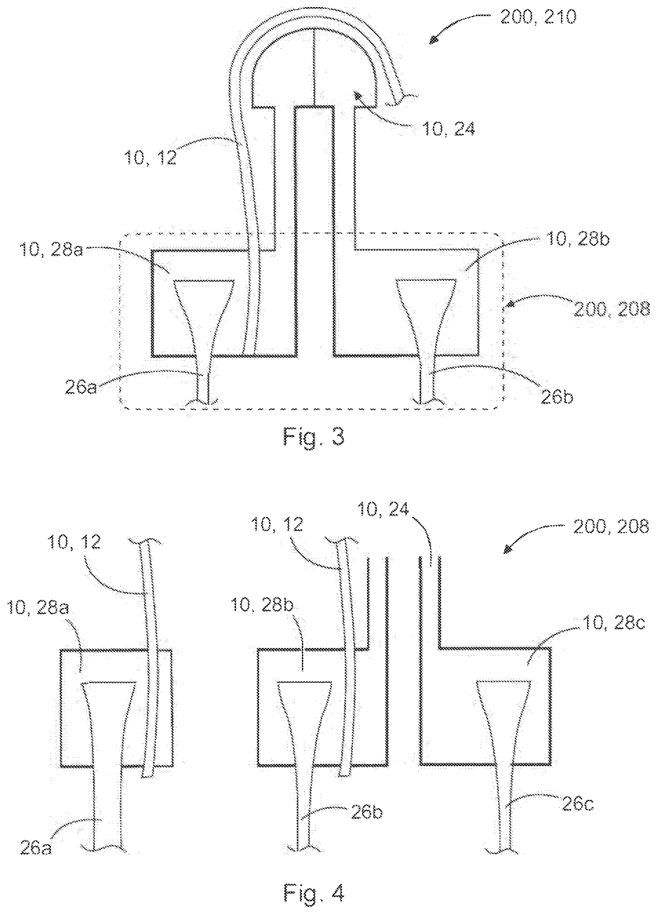

FIG. 3 shows a module 200, which is formed as a sensor terminal module 210. The sensor terminal module 210 further comprises a module 200, which is formed as a connection area 208. The sensor terminal module 210 and the connection area 208 each comprise multiple differently formed electric elements 10. The sensor terminal module 210 comprises a sensor element 24, a conductor strand 12, and electric terminals 28a, 28b. The electric terminals 28a, 28b together form the connection area 208. Preferably, the sensor element 24 and the connection area 208 with the electric terminals 28a, 28b together form the sensor terminal module 210. In particular, the sensor element 24 can be formed as a temperature sensor or as a pressure sensor. A temperature sensor is preferably adapted to detect the temperature of a heating device. A pressure sensor is preferably adapted to detect the pressure within a fluid-container 102 and/or the pressure generated by a vehicle occupant on a vehicle seat.

In addition, the sensor element 24 can be formed as a presence detector, which detects the presence of a vehicle occupant and/or a body part of the vehicle occupant and/or a movement of a body part of the vehicle occupant. The sensor element 24 can be connected to supply lines 26a, 26b via the electric terminals 28a, 28b. The end of the supply line 26a is connected, in particular soldered, to the electric terminal 28a. The end of the supply line 26b is connected, in particular soldered, to the electric terminal 28b. By means of the supply lines 26a, 26b, the sensor element 24 can be connected, for example, to a control unit, in particular to a vehicle control unit, and/or to a power supply device, in particular to a battery and/or a power supply unit, so that the sensor element 24 can be supplied with power and/or with data by means of the supply lines 26a, 26b, wherein the supply lines 26a, 26b are also adapted to transmit sensor data detected by the sensor element 24, for example temperature data and/or pressure data, to a control unit, in particular to a vehicle control unit.

At the electric terminal 28a, the conductor strand 12 is also connected to the electric terminal 28a together with the supply line 26a, in particular thermally welded, soldered or attached by ultrasonic welding. The conductor strand 12 can, for example, be formed as a heating strand, a sensor strand and/or a shielding strand. The conductor strand 12 has a bending contour such that it runs around the sensor element 24 in a contour substantially corresponding to the sensor element 24, in particular in a loop, wherein the section of the conductor strand 12 shown in FIG. 3 can, for example, be part of a heating device, a sensor device and/or a shielding device, which can be connected to a carrier element 22 and/or attached to a carrier element 22, in particular by means of ultrasonic welding. Preferably, the electric terminals 28a, 28b are formed at least 50% of copper or at least 50% of iron or at least 50% of the material of a supply line 26a, 26b attached thereto. The supply lines 26a, 26b can be internal conductor strands of an electrical device and/or external conductor strands of a power source.

FIG. 4 shows a module 200, which is formed as a connection area 208. The connection area 208 comprises various electrical elements 10. In particular, the electric connection area 208 is formed by three electric terminals 28a to 28c, wherein a supply line 26a and a conductor strand 12 are connected to the electric terminal 28a, a supply line 26b and a further conductor strand 12 are connected to the electric terminal 28b, and a supply line 26c is connected to the electric terminal 28c. Preferably, the supply lines 26a-26c and the conductor strands 12 are thermally welded, soldered or ultrasonically welded to the respective electric terminal 28a-28c. Preferably, the electric terminals 28b and 28c are part of a sensor element 24, as shown in FIG. 3. Preferably, the supply lines 26b and 26c form an electrical circuit with the sensor element 24, wherein the sensor element 24 can act as a switching device which can regulate the current flow in the electrical circuit by interrupting the circuit and closing the circuit.

A connection module is particularly cost-effective if at least one (external) supply strand 26a-c is connected to at least one (internal) conductor strand 12 with a terminal 28a-c connected in between. This connection serves as a flat anchor surface that is attached to a carrier material in advance. This connection technique requires less manual handling compared to soldering or crimping because all contact and connection zones are in the same plane as when laying other electrical functional elements in a module. In addition, only materials and forces perpendicular to this plane need to be applied to the terminal 28a-c during assembly.

Ultrasonic welding has the advantage that, unlike thermal welding or soldering, the electrical resistance of an embedded strand is hardly changed because heating the strand is not sufficient to significantly change the material structure of the strand.

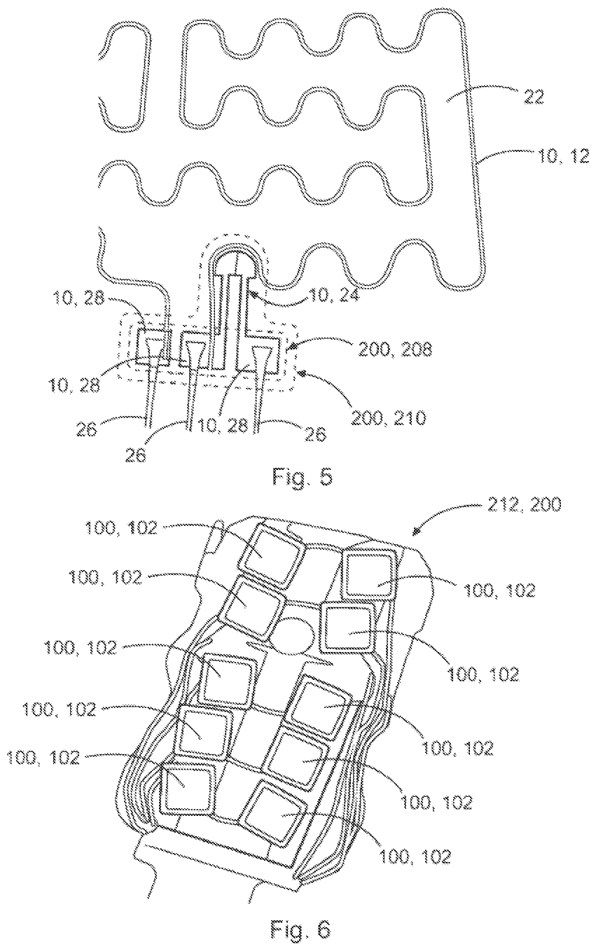

FIG. 5 shows a sensor terminal module 210 with a connection area 208 and a sensor element 24, wherein the sensor terminal module 210 is connected to an electric conductor strand 12 formed as a heating strand via the connection area 208. The conductor strand 12, which is formed as a heating strand, is attached to a carrier element 22, which is formed, for example, from foil made of a polymer, and in particular is connected to the carrier element 22 in a material-locking manner by means of ultrasonic welding. Preferably, the sensor terminal module and the heating strand together form a heating device 214. The sensor terminal module and/or the conductor strand 12 formed with the sensor terminal module and as a heating strand are supplied with electrical energy from a voltage source and/or with data from a control device, in particular a vehicle control device, via supply lines 26, which are connected to the sensor terminal module and the conductor strand 12 via electrical terminals 28, wherein sensor data determined by means of the sensor element 24, for example pressure or temperature data, can be transmitted to a control device via the supply lines. The heating device 214 formed from the sensor terminal module 210 and the conductor strand 12 formed as a heating strand can, for example, be connected in a material-locking manner to an inflatable fluid-container 102, in particular by means of ultrasonic welding, wherein the carrier element 22 is then a component of the fluid-container 102. An inflatable fluid-container 102 together with a heating device 214, which in particular comprises a sensor terminal module 210 and a heating strand, can in particular form a heating-contouring module 204 and/or a heating-massage module 206.

FIG. 6 shows a module 200 which is formed as a device 212 for adjusting the seat contour of a vehicle seat, or seat-contouring-module for short. The device 212 for adjusting the seat contour of a vehicle seat comprises multiple objects 100, in the illustrated embodiment example ten, formed as inflatable fluid-containers 102. Such a device 212 with multiple fluid-containers 102 is preferably arranged in one or more vehicle seats of a vehicle, in particular integrated into a seat cushion and/or a seat cover, and adapted to dynamically adjust the seat contour of the vehicle seat, in particular depending on driving maneuvers such as curve-driving, and/or to massage a vehicle occupant sitting on the vehicle seat. To adjust the seat contour and/or to massage a vehicle occupant, the inflatable fluid-containers 102 can be supplied separately and independently of each other with a defined amount of air in order to inflate them. One or multiple of the fluid-containers 102 can comprise a heating device 214, a sensing device, and/or a shielding device.

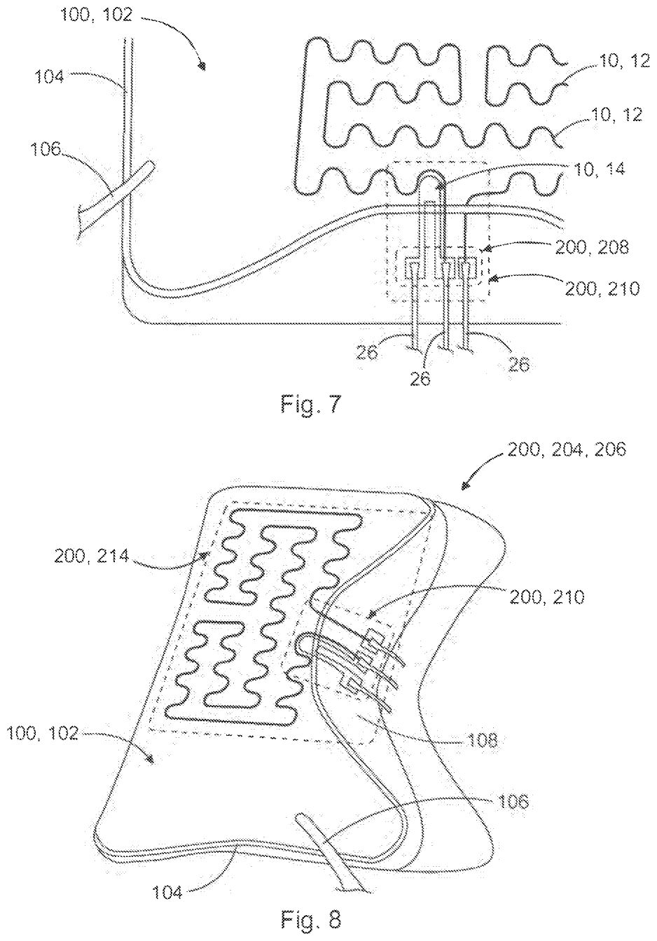

FIG. 7 shows a section of an inflatable fluid-container 102, which can be filled with air by means of a fluid line 106 and/or wherein air can be sucked out of the fluid-container 102 by means of the fluid line 106, so that a quantity of air present in the fluid-container 102 can be individually adjusted. If the fluid-container 102 is part of a seat contouring device, the contour of a vehicle seat can be individually adapted by inflating the fluid-container 102 with air and/or by extracting air from the fluid-container 102 by means of the fluid line 106, wherein the fluid-container 102 can also be part of a massage device for a vehicle seat for massaging a vehicle occupant. The fluid-container 102 shown in FIG. 7 further comprises a sensor terminal module 210 comprising a connection area 208 and a sensor element 14 as well as a conductor strand 12, which is preferably formed as a heating strand.

Via the connection area 208 of the sensor terminal module 210, supply lines 26 and the conductor strand 12 formed as a heating strand are connected to each other and to the sensor element 14 in an electrically conductive and/or signal-conducting manner. The sensor terminal module 210 preferably forms a heating device 214 together with the conductor strand 12. The inflatable fluid-container 102 is preferably formed as a bladder which can be filled with air, wherein the fluid-container is formed from two flexible walls which are impermeable to air. The flexible walls of the fluid-container 102 preferably consist of a polymeric material, in particular polyurethane, and are also formed as a bladder by welding the flexible walls together at their edges. Preferably, at least one flexible wall of the fluid-container 102 acts as a carrier element 22 for the conductor strand 12 formed as a heating strand, wherein the conductor strand 12 is preferably connected to the flexible wall of the fluid-container 102, which acts as a carrier element 22, by means of ultrasonic welding. In particular, the conductor strand 12 is ultrasonically welded on the inner surface of a flexible wall within the fluid-container 102 into the flexible wall, which serves as the carrier element 22, such that the conductor strand 12 is at least partially, preferably completely, embedded in the flexible wall of the fluid-container 102. In this way, the conductor strand 12 is both electrically insulated and protected from other external influences, in particular from mechanical damage.

For example, the sensor element 14 can be formed as a temperature sensor for monitoring the temperature of the conductor strand 12 formed as a heating strand or as a pressure sensor for monitoring the pressure within the inflatable fluid-container 102. Preferably, the inflatable fluid-container 102, the conductor strand 12 and the sensor terminal module 210 form a combined seat contour and seat temperature adjustment device, by means of which the comfort of a vehicle seat is increased by combining a contouring and massage function and a heating function. The sensor terminal module 210 and, in particular, the connection area 208 is welded between two protection layers. These protection layers are preferably layers of material that are already used for the module, e.g. airtight walls of a massage bladder.

The sensor element 14 can protrude from the welded region at least partially into the interior of the fluid-container 102. The remaining components of the sensor terminal module 210, in particular the connection area 208, is welded between two protection layers in such a way that the sensor terminal module 210 and/or the connection area 208 is sealed and thus protected against external influences, in particular against moisture, and electrically insulated, as well as protected against mechanical damage.

The two protection layers, between which the sensor terminal module 210 and/or the sealed connection portion 208 are welded, are preferably portions of the flexible walls of the fluid-container 102 which extend beyond the welded edges forming the bladder of the fluid-container 102. In addition, the protection layers can be separate protection layers that are not connected or welded to the fluid-container 102 or are subsequently attached to the fluid-container 102. Preferably, the sealed welded electrical connection area 208 and/or the sealed welded sensor terminal module 210 completely seals at least one electrical terminal 28, 28a-28c, wherein the welding between two protection layers avoids the need for complex, in particular time-consuming and cost-intensive gluing or coating or even the use of heat-shrink tubing to protect the connection area 208 and/or the sensor terminal module 210.

FIG. 8 shows a fluid-container 102 which is inflated with air, wherein the fluid-container 102 shown comprises an integrated heating device 214. The fluid-container 102 and the heating device 214 together form a heating-contouring module 204 and/or a heating massage module 206. The heating device 214 comprises a conductor strand 12 formed as a heating strand, which is embedded in the flexible wall of the upper flexible wall of the fluid-container 102 by ultrasonic welding. A sensor terminal module 210, via which a sensor element 14 and the heating strand are supplied with electrical energy, is welded in a sealing area 108 between extensions of the flexible walls of the fluid-container 102, so that the sensor terminal module and in particular the connection area 208 of the sensor terminal module 210 is sealed and protected from environmental influences. By welding, in particular embedding, the heating strand of the heating device 214 on the inside of a flexible wall of the fluid-container 102 and by welding and sealing the sensor terminal module 210 in the sealing area 108, which is formed by extending the flexible walls of the fluid-container 102, the heating device 214 and the fluid-container 102 form an integral part, which in particular facilitates mounting, for example in a vehicle seat.

Furthermore, the combination of a heating device with a fluid-container for a seat contouring device and/or a massage device for a vehicle seat significantly increases the comfort for a vehicle occupant due to the possibility of simultaneously massaging the vehicle occupant, adjusting the seat contour and/or simultaneously warming the vehicle occupant. Furthermore, the fluid-container 102 can comprise, as an alternative to the heating device 214 or in addition to the heating device 214, at least one sensor device, in particular with a capacitive sensor, for example by means of a sensor strand, and/or a shielding device, in particular by means of a shielding strand, wherein a sensor strand of the sensor device and/or a shielding strand of the shielding device can also be connected to the fluid-container 102 by ultrasonic welding, and/or wherein the shielding strand and/or the sensor strand can be supplied with data and/or with energy by means of the same sensor terminal module 210 or by means of separate sensor terminal modules 210. Heating strands and/or sensor strands and/or shielding strands can also be externally laminated to the surface of a wall of the fluid-container 102 using a separate carrier element 22 instead of being embedded in a flexible wall of the fluid-container 102.

The invention relates to an electrical functional element (10) for connecting to an object (100), preferably by adapting the electrical functional element (10) to be connected to the object (100) by means of ultrasonic welding.

The term “ultrasonic welding” means in particular:
a weld seam formed by melting two layers along a line,
an elongate melting zone of a single layer in which another body, in particular a conductor strand, is embedded during softening of the melting zone, and in which the body is held there after solidification of the melting zone.

### Part 2 of the Description

The invention relates to at least one of:
1. an electric element attached to an object,
2. an object, having at least one electric element attached to it,
3. a module, having at least
   an electric element,
   an object and
   at least two different dynamic functions
4. a method of attaching an electric element to an object.

Such electric element preferably is at least one of
a conductor strand,
a sensor,
an electric connector,
a shielding device against electromagnetic influences,
an electric heating device.

Such object preferably is at least one of:
an vehicle interior component, especially an armature, an arm rest, a door cover or a vehicle roof,
a heated vehicle component,
a steering wheel,
an inflatable fluid-container,
a vehicle seat, especially a seat cover, head rest or head side rest.

Such module preferably is at least one of:
a heater-presence detection-module for a steering wheel,
a heater-presence detection-module for a vehicle panel,
a heater-contouring-module for vehicle seat,
a heater-massaging-module for vehicle seat,
an inflatable fluid-container with integrated heating device,
a sealed electric connection area,
a sensor-terminal-module.

Such dynamic function preferably is at least one of:
heating a person,
detecting a person,
massaging a person,
adjusting the contour of a body supporting device,
adjusting the volume of an inflatable fluid-container.

Preferably such body is that of a person.

Preferably such person is a passenger of a vehicle, especially a driver.

A dynamic function means a function, which requires an active influence of the system to any parameters of operation, especially on fluidic and electric currents.

Such attachment preferably is at least by one of
ultrasonic welding,
soldering, and
thermal welding.

Ultrasonic welding means attaching by submitting at least one of the fixed objects to pressure and vibration in a frequency range of ultrasonic sounds.

A fixation by ultrasonic welding allows a good bonding between an electric element, especially a conductive strand, and a carrier substrate, e.g. a flat layer. This fixation gets especially strong by forming an adhesive connection, especially I if wire coating and substrate material are melting together as a result of the ultrasonic treatment.

Soldering means fixing by adding molten material, with the added material being at least one of:
an electrically conductive material, at least in its sold state,
a material containing at least 50% tin, lead or another metal or alloy with a melding temperature below 500 C, preferably below 300 C,
having a melting temperature, which is higher than at least one of the fixed components, preferably higher than all fixed components.

Thermal welding means fixing by melting material, with the material being at least one of:
a part of at least one of the spare parts to fix to each other, and
additional material, containing at least 50% iron, aluminum or another metal or electrically conductive alloy with a melting temperature above 250 C.

The invention and its components are explained and specified hereafter in further detail.

FIG. 1 shows a cross section through a multifil strand made of multiple monofil insulated conductor strands.

A strand is preferably at least one of:
a lengthy element, having a mainly linear extension. (‘Linear’ here means ‘in the form of a straight or curved line’.)
a mainly 1-dimentional textile element
a fiber- or filament-based spare part.

A strand preferably is at least one of
a monofil strand
multifil strand.

A strand preferably is at least one of
a strand with electric function especially for heating, sensing and shielding
a strand with mechanical function especially for removing tension and bending forces from strands with electric function.

An electric element can be a conductor strand.

A conductor strand is a strand that is at least partly electrically conductive.

A conductor strand preferably has at least one of the general features of a strand.

### A conductor strand preferably is one of:

a resistance heater, a shielding conductor, an antenna, a sensor conductor.

A conductor strand preferably is at least one of:
a monofil strand
multifil strand.

A conductor strand can contain at least one of:
one or more non-conductive strands and
one or more conductive strands (as sub-strands).

That means, a conductor strand can have
a multitude of conductive (sub-) strands, at least one of which is coated with two layers, having at least one difference in property
a joint coating with two layers, having at least one difference in property.

Such conductor strand preferably is selected to allow bending radii of 1 mm, e.g. by selecting the strand diameter below 0.2 mm

Such conductor strand preferably has an electric resistance in the range of 0.5 and 3 Ohm/m, preferably between 1 and 2 Ohm/m, preferably 1.2 and 1.8 Ohm/m, especially if the conductor strand is a heater strand.

A monofil conductor strand preferably has at least one of:
an electrically conductive core
a first layer at least partly surrounding such core
a second layer.

Such monofil conductor strand preferably is at least one of:
a sensor strand, especially one of a capacitive presence detector, and
a shielding strand, especially one decoupling a heating device from a presence detector.

Such filament core preferably is a metal filament, preferably at least partly made from at least one of:
copper or copper alloy, and
steel or an iron alloy.

Such first filament layer preferably is at least one of:
an electrical insulation layer,
a protection layer for absorbing mechanical stress, like ultrasonic vibrations.

Such first filament layer preferably has at least one of these features:
It is at least partly made of a polymer.
It is at least partly covering the core.
It has a melting temperature above 220 C, preferably above 240 C, preferably above 300 C.
It at least partly has a thickness below 0.5 mm, better less than 0.01 mm, ideally below 0.01 mm.

Such second filament layer preferably is at least one of:
an electrical insulation layer,
a fixation layer.

Such second filament layer preferably has at least one of these features:
is at least partly covering the core,
is at least partly covering the first layer.
has a melting temperature lower than the melting temperature of the first layer, preferably below 250 C, preferably below 200 C.

Such second filament layer preferably has at least one of these features:
It is at least partly made of a polymer.
It is at least partly covering the first layer.
It is at least indirectly covering the core at least partly.
It has a melting temperature lower than the melting temperature of the first layer, preferably below 250 C, preferably below 200 C. Preferably the melting temperature is at least 20 C lower than that of the first filament layer, better 50 C.
It at least partly has a thickness below 0.5 mm, better less than 0.01 mm, ideally below 0.01 mm

Such multifil strand preferably has at least one of
a number of strands with electric function, especially for heating, sensing and shielding
a number of strands with mechanical function especially for removing tension and bending forces from strands with electric function.

Such numbers being chosen from 1 to 150.

For conductive strands/filaments the number is preferably from 2 to 8.

A multifil conductor strand preferably has at least one of:
a number of electrical conductor strands
a heating strand
a sensor strand
a non-conductive carrier of mechanical tension. (like a mineral fiber, preferably containing glass).
Multifil strands have the advantage to increase the adhesion to a carrier compared to a monofil strand of similar diameter. This is especially valid for an multifil conductor strand being free of an outer mantle.

A carrier like shown in FIG. 2a is carrying a number of electric functional elements. (The number being chosen from 1 and a multitude).

Such carrier preferably is a carrier of at least one of:
a flat heating device, a shielding device, a sensor device and an electric terminal.

Such carrier preferably is at least one of:
a flat polymeric material layer,
a wall of an inflatable fluid-container, especially a pneumatic bladder of a massage device or a vehicle seat
an dielectric layer of a shielding device,
a cover of a seat or other vehicle interior.

Such carrier preferably has a thickness between 0.1 mm and 3 mm,
preferably has a thickness between 0.1 mm and 1 mm,
preferably has a thickness between 0.1 mm and 0.6 mm,
if the carrier is a flat layer.

Such carrier has a melting temperature above temperatures, which appear during ultrasonic welding, preferably above 200 C, preferably above 250 C, preferably above 400 C.

Such carrier preferably carries electric elements on multiple of its sides.

If the carrier is a layer product, this means, the carrier carries electric elements on both of its opposing surfaces.

That allows to easily insulate such electric elements electrically from each other. ‘Layer product’ means a basically 2-dimensional element, even if it is curved in a third dimension.

If such carrier carries conductor strands on both of its surfaces, the thickness of the carrier is preferably at least 50% of the combined thickness of the thickest strand of each of both surfaces.

Depending upon the depth of penetration of such strands into the carrier during ultrasonic welding, it can be preferred to choose a minimum thickness of the carrier to equal at least the sum of a thickness of a thickest strand on one surface of the carrier and of a thickness of a thickest strand on its opposing surface of the carrier.

This avoids completely cutting off the carrier from both sides.

If such carrier carries multiple separate conductor strands, the patterns of such strands are adjusted to each other, especially if the strands are on opposing surfaces of the carrier, especially if the carrier thickness is thinner than the combined thickness of the involved strands.

In such cases, the layer pattern avoids sections, where the strands run along each other in an overlapping way.

This avoids completely cutting off the carrier from both sides.

Such carrier preferably is made at least partly from one of
an electrically insulating material e.g. Poly-Urethan. (This allows to leave out further insulation material within a device.)
a stretchable material. (‘Stretchable’ means, such material allows the carrier to extent of at least 5-15% without material damage, at least without significant damage.

This is especially important, if the carrier is applied to a steering wheel, especially as a carrier of a heating element, a shielding element or a capacitive sensor.)

At least one strand is attached to the carrier in a layer pattern.

The pattern depends upon the function of the strand.

To build such layer pattern preferably at least one strand is at least partly arranged in one of:
a wave-like pattern, especially in the form of a sinus wave.
   (Such pattern allows the strand to compensate mechanical stress by following a stretching of the carrier. Sinus-waves are especially reliable for heating strands.)
a zig-zag pattern having,
   multiple straight line sections,
   multiple intermediate bendings, e.g. by 90 degree,
   an area, where two strands or strand sections are arranged in parallel, (this can be two sections of the same strand or a neighboring strand)
   a distance between such two parallel strands or strand sections, with the distance being less than 5 mm, preferably less than 2 mm, preferably 1 mm or less.
   (This is specially suitable for shielding strands to ensure a proper shielding of electromagnetic influences.)
a pattern having multiple U-turns with
   multiple straight line sections,
   multiple intermediate bendings by about 180 degree,
   a distance between such two parallel strands or strand sections, with the distance being less than 5 mm, preferably less than 2 mm, preferably 1 mm or less.
   (This is specially suitable for shielding strands or heating strands.)

A sensor preferably is at least one of
a temperature sensor, especially for monitoring a heating device, especially an NTC or a thermostat or a thermistor,
a pressure sensor, especially for controlling an inflatable fluid-container,
a presence detector, especially for detecting hands, persons or movements, especially a capacitive detector, especially one with at least one textile or film representing a capacitor plate of such capacitor.

It can be a temperature sensor like shown in FIG. 3 on an electrode like in FIG. 2b as a part of capacity for detecting the presence of an seat occupant.

Such sensor is preferably preassembled to form part of a sensor device, especially if it is a device for monitoring temperature or for indicating certain temperature thresholds.

A sensor device has preferably at least one of:
at least one sensor,
at least one supply line, having at least one of these functions:
   providing the sensor with energy and signals,
   guiding data from the sensor to a control device. (Such control device could be part of the object or be outside, e.g. in the vehicle ECU.

A sensor device preferably has at least one sensor having at least two supply lines,
which connect the sensor to two electric potentials differing from each other,
with the sensor and the two supply lines forming part of an electric loop,
with the sensor being a switching device regulating an electric flow through that loop.

An electric terminal preferably like in FIGS. 3 and 4 is an electrically conductive base, which is connected to at least one of:
an internal electric element of a connected device, especially a conductor strand of a heating device, a sensor device or a shielding device, (internal=inside or attached to an object with electric function),
an electric conductor towards an external source of electricity. (external=outside or with distance to the object with electric function).

Such base can be a metallic plate or a section of conductive film, preferably in the form of a square or rectangle.

Such electric terminal preferably is made of at least one of:
at least 50% copper,
at least 50% iron,
at least 50% of the same material like a connected internal conductor strand, and
at least 50% of the same material like a connected external conductor.

Preferably an internal conductor strand, an external conductor and their electric terminal are all made of at least 80% copper, preferably at least 95 % in weight.

Such electric terminal preferably is connected to at least one of:
an internal electric element via soldering, and
an external source of electricity via resistance welding.

A sensor-terminal-module (e.g. like in FIGS. 3 and 4) has
at least two electric terminals,
a sensor,
   having at least two supply lines,
   with a first supply line connected to the first electric terminal,
   with a second supply line connected to the second electric terminal. This allows a simplified electric connection of flat functional models, like heating, shielding or sensor devices.

Preferably at least one sensor supply line and one electric terminal are forming an integral part.

The integral part preferably is made of a conductive plate, sheet or film.

The integral part preferably is fixed to a carrier.

Such carrier can be a separate connector carrier or a carrier of an electric module like a heating, shielding or sensing device.

This reduces the number of parts and simplifies the assembly.

A sensor-terminal-module preferably has at least:
three electric terminals,
a sensor,
   with a first supply line connected to a first electric terminal,
   with a second supply line connected to a second electric terminal,
at least two ends of conductor strand for connecting an electric element different than the sensor to an external voltage source,
   the first of such ends being connected to one of the first and second terminal (like the sensor)
   the second end being connected to the third terminal (unlike the sensor). This allows to operate two different electric elements (like the sensor and a heating device) independently from each other with only three instead of four external supply wires.

Preferably such end of conductor strand is the end of at least one of:
a heating strand,
a grounding line of a shielding device and
a connection line of a capacitor layer of a capacitive sensor.

Preferably the two ends of conductor strand are at least one of:
a first and second end of the same heating strand, and
a grounding line of an electromagnetic shielding device and
a connection line of a capacitor layer of a capacitive sensor.

This allows to significantly reduce a required space for a connection area, e.g. of a surface heating device, e.g. from about 60×100 mm with conventional crimping of wires to about 30×30 mm according to the invention.

Preferably such sensor-terminal-module has a terminal carrier in addition to a carrier of an electric element different from the sensor.

This especially simplifies an assembly, if the number of terminals is larger than two,

A sensor-terminal-module preferably has at least:
an electric terminal
a conductor strand of an electric element,
a sensor device for monitoring at least one of:
   the electric element and
   the conductor strand,
a supply line, connecting the sensor to the electric terminal
with the conductor strand and the supply line both being electrically and mechanically attached to the same electric terminal.
   This allows to make precise measurements due to the proximity of the sensor to the conductor strand.

Preferably such sensor-terminal-module further includes at least one of:
The sensor is arranged with a distance of less than 2 cm to the conductor strand, preferably less than 5 cm, preferably less than 2 mm.
The conductor strand forms a loop-like section, which surrounds the sensor at least partly.
The sensor device having
   a guiding device
      for guiding a section of the conductor strand in a defined way at least partly around the sensor,
      forming at least a section of a circle, especially a semi-circle.
   A sensor positioned in the center of such circle. This allows to generate measurement close enough to the sensor for being precise and distant enough to allowing a stable control.

A heating device (like in FIGS. 7, 8 and 9) preferably has a function of heating at least one of:
a surface of a vehicle interior, especially an armature, a door,
an armrest, a pillow or cushion of a vehicle seat or a steering wheel,
a battery heating device, and
a patient heating device, especially a disposable one-way heating blanket.

A heating device preferably has at least one of:
a carrier, carrying an electric element,
an electric heating resistor, and
an electric strand, especially a heating strand.

Preferably at least one electric element is fixed to the carrier
in a way, which is free of textile stiches and free of sewn seams,
preferably by ultrasonic welding.

Preferably such electric element is a strand, which is fixed at least partly along its length to the carrier.

A heating device preferably has at least one of:
a heating strand attached to a film carrier, which carrier can be or is fixed onto an object for heating
a heating strand attached to a film carrier, which carrier can be or is fixed to a cover of an object for heating, preferably with the heating device between the object and its cover,
   (If a diameter of the strand is chosen to be smaller than the thickness of the carrier, this allows the manufacturing of an efficiently heated object without read-though effect on its surface.)
a heating strand directly attached to a cover of an object, preferably with the heating device between the object and its cover,
   (This allows the use of especially thin strands and an operation of a heater with low energy losses.)
a heating strand attached to the surface of an object for heating, and
a heating strand attached to an object by at least partly embedding it into the surface of the object.
   (This allows the manufacturing of plastic parts with embedded strands without read-though effect on their surface, e.g. steering wheels, door panels or side cushions of head rests, especially if such objects are at least partly made of a polymeric material, especially a thermoplastic material.)

Such attachment preferably includes at least one processing zone subjected to ultrasonic welding.

Such heating device preferably has at least one of:
a multifil heating strand with at least one of these filaments having a double-layer-coating
a sensor-terminal-module
a connector zone on a heating device, which electrically connects with a voltage source just by assembling a heatable object into its intended position (e.g. a panel with heating device to a door, or a heated sheet to its frame)
a heating strand with at least one of:
   being applied directly to a heatable cover (without intermediate cushioning material layers)
   being made at least partly from metal.
   having a monofil having a diameter below 1 mm, preferably below 0.1 mm, preferably below 0.01 mm.
being a multifil having a diameter below 1 mm,
preferably below 0.1 mm, preferably below 0.01 mm.

A heater layer preferably has
a carrier layer, preferably of insulation material, preferably of a thickness of at least 0.7 mm.
a heating strand, embedded into the carrier layer. preferably of a thickness of not more than 0.2 mm diameter.

A shielding device (e.g. like in FIG. 2b) preferably reduces the effect of electromagnetic influences, especially if placed between a heating device and a sensor device, especially in a multi-layer-sandwich with:
a heating device for heating hands of a driver of a vehicle.
a sensor device for monitoring the hands of the driver and
a shielding device for decoupling the heating device from the sensor device. avoiding electromagnetic effects of

Such shielding device has a carrier and at least one shielding conductor, which is preferably an electric strand.

Such shielding device has at least one of:
a carrier with any of the features previously described for carriers,
a shielding strand with any of the features previously described for conductor strands,
a shielding strand with any of the features previously described for heating strands,
an attachment between carrier and strand as previously described,
a shielding strand attached to the carrier free of stitches or sewing seams.

Such shielding device can have a carrier, which is carrying a shielding conductor and at least one of:
a presence detector strand and
a heating conductor.

Preferably such conductor strands of different function are at least one of:
attached to opposing surfaces of the carrier,
embedded from opposing sides of the carrier,
following a layer pattern different from each other,
keeping a minimum distance towards each other with the distance being sufficient for keeping them electrical insulated from each other.
having a thickness which combined is smaller than the thickness of the joint carrier.

A presence detector device (e.g. like in FIG. 2b) preferably is a sensor for detecting changes in an field, with the field preferably being an electric, a magnetic or both.

A presence detector device preferably has:
a presence detector strand, for detecting a presence or a movement of a human body part.

Such presence detector device preferably has a detector strand capable of at least one of:
indicating changes of an electromagnetic field in the surrounding of the detector strand, especially changes caused by the presence of water within the body parts, and
indicating pressure changes in the surrounding of the detector strand, especially changes caused by the weight of monitored body part.

Such presence detector device has at least one of:
a carrier with any of the features previously described for carriers,
a detector strand with any of the features previously described for conductor strands,
a detector strand with any of the features previously described for heating strands,
an attachment between carrier and strand as previously described,
a detector strand attached to the carrier free of stitches or sewing seams.

Such Presence Detector Device Can Have a Carrier, Which Is Carrying a Detector Strand and at

least one of:
a shielding strand and
a heating conductor.

Such presence detector device preferably is quite similarly built like the shielding device.

It therefore can have adopt any further feature as described for the shielding device.

A heater-presence detection-module (e.g. like in FIGS. 5, 7, 8) preferably includes at least two of:
a heating device,
a shielding device and
a heating device.

Preferably multiple of such devices form a joint module, having a multi-layer sandwich structure.

Preferably at least two of such structures are arranged on parallel levels, electrically insulated from each other, e.g. by a carrier layer. (They could also make use of the same conductors and using them at different times, e.g. by multiplex switching.)

Such heater-presence detection-module preferably has at least one conductive strand of a thickness along a range from 0.05 mm to 1.5 mm,
preferably 0.1 mm to 0.5 mm, preferably 0.1 mm to 0.3 mm.
preferably being at least one of a heating strand, a sensor strand and a shielding strand.

Such conductor strand preferably is a multi-filament,
preferably with a number of 1 to 10 filaments for a sensor strand,
preferably with a number of 1 to 3 filaments for a shielding strand,
preferably with a number of 1 to 100 filaments for a heating strand.

A heater-presence detection-module for a steering wheel preferably has a stretchability of at least 5-15% without influence to carried electric elements or modules.

Such heater-presence detection-module can also be embedded into a door panel, an armrest or a pillow of a vehicle.

Such heater-presence detection-module preferably has
a heater carrier, preferably of insulation material, preferably of a thickness of at least 0.7 mm and
attached to or embedded into the carrier a heating strand, preferably of a thickness of not more than 0.2 mm diameter.

Such heater-presence detection-module preferably has
a sensor carrier, preferably of insulation material, preferably of a thickness of at least 0.7 mm.
attached to or embedded into the carrier a sensor strand, preferably of a thickness of not more than 0.2 mm diameter.

Such heater-presence detection-module preferably has
a shield carrier, preferably of insulation material, preferably of a thickness of at least 0.7 mm.
attached to or embedded into the carrier a shielding strand, preferably of a thickness of not more than 0.2 mm diameter.

Such heater-presence detection-module preferably has a carrier, which is at least one of:
which is a combination of a heater carrier and shielding carrier, with a heating strand and a shielding strand fixed on opposing surfaces of the combined carrier
which is a combination of a sensor carrier and shielding carrier, with a sensor strand and a shielding strand fixed on opposing surfaces of the combined carrier.

A seat contour adjustment device (e.g. like FIG. 6) is capable of adjusting the contour of a seat in order to at least one of:
adjusting the seat to the anatomy of a specific user,
adjusting the seat to compensate a driving maneuver, especially for counterbalancing quick curve-driving,
adjusting the seat to avoid disadvantages of keeping a passenger in the same body posture for to long,
adjusting the seat to indicate situations, like sleepiness, or prepare the passenger for predicted events, like collisions,
massaging defined areas of a seat surface with increased temperature and pressure.

Such seat contour adjustment has multiple inflatable fluid-containers, which jointly adjust the contour of a seat. At least one of them is a container-heater-module as shown in FIG. 8, having an inflatable fluid-container with integrated heating device.

An inflatable fluid-container preferably can be filled with an amount of air at least during certain phases of operation. Preferably the fluid is air.

An inflatable fluid-container preferably has at least one flexible wall, which is impermeably for the contained fluid. That allows to change the contour of that wall and/or the fluid-container by changing the amount of fluid within the fluid-container.

Such fluid-container wall is made at least partly of material not getting damaged by US welding.

Preferably such wall is made of polymeric material, preferably poly-urethan.

Preferably such wall has a melting temperature, which is higher than that of at least one coating of a carried strand, preferably by at least 20 C, preferably at least 50 C.

Such fluid-container wall preferably has a thickness that is thicker than any conductor strand.

Preferably the wall has a thickness between 0.1 mm and 5 mm,
preferably has a thickness between 0.1 mm and 2 mm,
preferably has a thickness between 1 mm and 2 mm.

An inflatable fluid-container preferably is made by attaching two layers of flexible wall material to each other.

The layers preferably have similar size and are sealed along their edges, preferably by welding them to each other.

One of the edges can also be result of just folding a larger sheet into two overlapping layers.

The result preferably is a gas-filled bladder.

An inflatable fluid-container preferably has at least one of:
an electric heating element,
a temperature sensor for monitoring the temperature of such heating element,
a temperature sensor for monitoring the temperature of a passenger,
a pressure sensor for monitoring pressure within an inflatable fluid-container,
a presence-detector for detecting human body parts, and
a shielding device for shielding electromagnetic influences, especially from the heating device towards a passenger or a presence-detector.

Preferably such electric elements and devices are integrated into the fluid-container.

A fluid-container wall preferably carries a sensor, preferably at least one of:
a temperature sensor, a thermistor, a thermostat, an NTC
a pressure sensor.

A seat contour adjustment device is preferably combined with a heating device, for at least one of:
general comfort and
supporting a massage of defined areas with increased temperature and pressure.

A seat contour adjustment device Preferably has at least one feature described for an inflatable fluid-container.

Preferably that is by incorporating such fluid-bladder or an additional separate assembly.

An inflatable fluid-container preferably has an integrated heating device, which preferably is at least one of:
embedded into a wall of the fluid container,
embedded into the fluid container from within, with the heating device attached to a flexible wall of the fluid-container, preferably to a side of the fluid-container, which is oriented towards a seat passenger.

If the heating device is enclosed inside the fluid-container, it can be made of from any suitable carrier material and heating conductor, e.g.
a carbon-multifilament on a fleece-carrier.
a litz-wire made from steel or copper on a knitted carrier
a sewn heating strand on any flat and flexible carrier.

If a heating strand is attached to a separate carrier, such carrier can be laminated to the flexible wall of the fluid-container.

The most simple way is a copper-multifil strand directly attached to a wall of the fluid container by ultrasonic welding. The strand may even be embedded within the wall from an inner surface of the fluid-container.

An assembly within the fluid-container protects the heater from mechanical loads, especially from shear movements outside the fluid-container.

If the heating device is attached to the fluid-container from outside the fluid-container, it can also be made in any of the previously described ways.

But its lifetime can be significantly increased if a heating strand is directly attached to a wall of the fluid container or at least partly embedded into the wall of the fluid-container by ultrasonic welding.

One or more of such inflatable fluid-containers with integrated heating device can form at least one of:
a heater-massaging-module for vehicle seat
heated contouring-module for vehicle seat

Preferably at least one of such containers is equipped with a sealed electric terminal zone as in FIGS. 7 and 8.

A sealed electric terminal zone preferably has a electric terminal or sensor-terminal module as previously described.

Preferably it serves for electrically contacting of at least one of:
an occupant-detection device,
a heating device,
a sensor device, especially for sensing pressure or temperature,
a shielding device.

A sealed electric terminal preferably is preferably positioned between two protection layers.

Such protection layer preferably is at least one of:
a carrier of an electric element or device, which is connected to an external voltage source or control device via such terminal
a separate protection layer of a suitable, preferably sealable material.
an extension of a wall of a fluid-container

Preferably the sealed electric terminal zone is sealed completely around at least one electric terminal, preferably around the complete terminal module.

That avoids time-consuming gluing or coating of contact areas or even shrinking tubes.

If a fluid-container is provided with a sealed electric terminal, preferably the two protection layers are extensions of the walls of the fluid-container, preferably of an upper and a lower wall of the fluid container.

Preferably the terminals are sealed between such two layers.

If a fluid-container is provided with a sensor-terminal module and a sealed electric terminal zone,
preferably at least one sensor of such sensor-terminal-module is placed within the fluid-container,
while a terminal section of such sensor-terminal module is inclosed within the sealed electric terminal zone.

This allows a precise measurement and a very simple assembly.

This is especially useful, if at least one of:
a heater device is placed within the fluid-container and at least one sensor is a temperature sensor,
at least one sensor is a pressure sensor, and
a presence detector, positioned with in the fluid-container.

A massaging device can be any Such Device in General, Not Necessarily Restricted to an application in vehicles.

That includes beds, massage tables, surgical table or deckchairs.

Such device can be provided with any feature as described for seat contour adjustment devices.

### REFERENCE NUMBERS

10 Electrical functional element
12, 12a, 12b Conductor strand
14 Partial strands
16 Wire
18 Protection layer
20 Melting layer
22 Carrier element
24 Sensor element
26, 26a-26c Supply line
28, 28a-28c Electric terminal
100 Object
102 Fluid-container
104 Welding area
106 Fluid line
108 Sealing area
200 Module
204 Heating contouring module
206 Heating massage module
208 Connection area
210 Sensor terminal module
212 Device
214 Heating device

1.-21. (canceled)

22. A sensor terminal module comprising:
at least two electric terminals; and
a sensor;
wherein the sensor has at least two supply lines;
wherein a first supply line of the at least two supply lines is connected to a first electric terminal of the at least two electric terminals, and a second supply line of the at least two supply lines is connected to the second electric terminal of the at least two electric terminals;
wherein the sensor terminal module comprises at least one object or a carrier to which at least one of the at least two electric terminals and/or the sensor is connected by ultrasonic welding.

23. The sensor terminal module according to claim 22, wherein at least one of the at least two supply lines and an electric terminal form a one-piece part, the one-piece part is produced from a conductive plate, a metal sheet or a foil, and/or wherein the one-piece part is fixed to the object formed as the carrier.

24. The sensor terminal module according to claim 22, comprising at least three electric terminals and the sensor;
wherein the first supply line is connected to a first electric terminal, the second supply line is connected to a second electric terminal;
at least two ends of a conductor strand for connecting an electrical element, which is not a sensor, to an external voltage source;
wherein a first end of the at least two ends is connected to one of the first terminal and the second terminal; and
wherein a second end of the at least two ends is connected to the third terminal.

25. The sensor terminal module according to claim 24, wherein the first end or the second end of the conductor strand is at least one of: i) a heating strand, ii) a grounding line of a shielding device, and iii) a connection line of a capacitor layer of a capacitive sensor.

26. The sensor terminal module according to claim 24, wherein the at least two ends of the conductor strand are: at least one of: i) a first and a second end of the same heating strand, ii) a grounding line of an electromagnetic shielding device, and iii) a grounding line of a capacitor layer of a capacitive sensor.

27. The sensor terminal module according to claim 24, wherein the sensor terminal module comprises a terminal carrier as a carrier for at least one of the electric terminals and/or the sensor and in addition to a carrier of an electric element other than the sensor.

28. The sensor terminal module according to claim 22, wherein the sensor terminal module has at least: i) an electric terminal, ii) a conductor strand of an electrical element, iii) a sensor device for monitoring at least one of: the electrical element and the conductor strand, iv) a supply line that connects the sensor to the electric terminal; wherein the conductor strand and the supply line are both electrically and mechanically connected to the same electric terminal.

29. The sensor terminal module according to claim 24, wherein the sensor is arranged at a distance of less than 2 cm from the conductor strand, and/or the conductor strand forms a loop-like section which at least partially surrounds the sensor, and/or has a sensor device comprising the sensor, which comprises a guiding device for guiding a section of the conductor strand at least partially around the sensor in a defined manner, whereby at least a section of a circle is formed and wherein a sensor is arranged in a center of the circle.

30. The sensor terminal module according to claim 22, wherein the sensor is at least one of a temperature sensor, a pressure sensor, or a presence detector.

31. A module comprising:
at least one electrical functional element;
at least one object;
wherein the module has at least two different dynamic functions which require active influencing of the module on any operating parameters comprising fluid flows or electrical currents; and
wherein the electrical functional element and the object of the module are connected to each other by means of ultrasonic welding in a material-locking manner.

32. The module according to claim 31, wherein the module is selected from one of the following assemblies:
i) a detection module for detecting heating energy on a steering wheel,
ii) a detection module for detecting heating energy on a vehicle cover,
iii) a heating contouring module for a vehicle seat,
iv) a heating massage module for a vehicle seat,
v) an inflatable fluid-container with integrated heating device,
vi) a sealed electric connection area, and
vii) a sensor terminal module.

33. The module according to claim 31, wherein at least one dynamic functions of the module is selected from:
i) warming of a person,
ii) recognizing presence of the person,
iii) massaging the person,
iv) adjusting the contour of a body supporting device, and
v) adjusting the volume of an inflatable fluid-container.

34. The module according to claim 31, wherein the module is a presence detector module for detecting at least one of presence and movement of a human body part.

35. The module according to claim 31, wherein a detection module for detecting heating energy is provided with at least one of the following components:
i) a sensor device,
ii) a heading derive, and
iii) a shielding device.

36. The module according to claim 31, wherein the module is a device for adjusting the seat contour of a vehicle seat.

37. The module according to claim 31, wherein the module comprises at least one inflatable fluid-container, at least one conductor strand, and at least one sealed sensor terminal module.

38. The module according to claim 31, wherein the module has an inflatable fluid-container with an integrated heating device and forms at least a part of a heating contouring module for vehicle seats.

39. The module according to claim 31, wherein the module has an electric connection area which is sealed from external influences by an ultrasonic welding in at least one protection layer.

40. The module according to claim 31, wherein the module has a massaging device with an air bubble, which is formed by welding two layers of material by means of ultrasonic welding.

41. An inflatable fluid-container for a seat contour adjustment or a massage function, for a vehicle seat, with at least one flexible fluid-container wall which is impermeable to the fluid contained therein, wherein the fluid container wall is at least partially produced from a material that is not damaged by ultrasonic welding, wherein the inflatable fluid-container has an electrical functional element, the electrical functional element is one of:
i) an electric heating element,
ii) a temperature sensor for monitoring the temperature of such a heating element,
iii) a temperature sensor for monitoring the temperature of a passenger,
iv) a pressure sensor for monitoring the pressure in an inflatable fluid-container,
v) a presence detection device for detecting human body parts, and
vi) a shielding device for shielding electromagnetic influences from the heating device to a passenger or a presence detection device,
wherein the electrical functional element is connected to the fluid-container wall by ultrasonic welding.

42. The inflatable fluid-container according to claim 41, wherein the heating element is a heating strand which is embedded in whole or in part by ultrasonic welding in the wall of the fluid-container.

43. The inflatable fluid-container according to claim 41, wherein the heating strand is arranged inside or outside the fluid-container.

44. The inflatable fluid-container according to claim 41, wherein the inflatable fluid-container comprises a sealed electrical connection zone.

45. The inflatable fluid-container according to claim 44, wherein the sealed electric connection zone has an electric terminal or a sensor terminal module that serves for the electric contacting of at least one of:
i) a seat occupancy detection device,
ii) a heating device comprising at least one heating strand,
iii) a sensor device, in particular for detecting pressure or temperature,
iv) a shielding device.

46. The inflatable fluid-container according to claim 41, wherein the heating device comprises at least one heating strand is arranged in the fluid-container and further comprising:
i) at least one temperature sensor,
ii) is at least one pressure sensor, and
iii) a presence detection device arranged in the fluid-container.

47. An electrical functional element or a steering wheel, comprising a carrier element and a heating device, a shielding element against electromagnetic interferences, and a sensor element, at least one of which is connected to the carrier element by ultrasonic welding.

48. The electrical functional element according to claim 47, wherein the heating device comprises an electric heating resistor and at least one heating strand, wherein the heating strand is at least partially embedded in the carrier element.

49. The electrical functional element according to claim 47, wherein the carrier element is produced from an electrically insulating material, and/or a stretchable material which allows an extension of 5-15%.

50. The electrical functional element according to claim 47, wherein the electrical function element comprises a multi-layer sandwich structure of a heating device, a shielding device and a sensor device comprising a temperature sensor or presence sensor, wherein the shielding device is arranged between the heating device and the sensor device.

51. The electrical functional element according to claim 47, wherein the shielding strand, the sensor strand, and/or the heating strand are attached to opposite surfaces of the carrier element and/or are embedded from opposite sides of the carrier element, and/or the different strands follow a different layer pattern and/or the strands maintain a minimum distance from each other, wherein the distance is sufficient to insulate them electrically from each other, wherein the thickness of the conductors in total is less than the thickness of the common carrier element.

52. A steering wheel comprising the electrical functional element according to claim 47.

53. A method of connecting at least one electrical element to at least one object, wherein the electrical element comprises a multifil conductor strand comprising multiple sub-strands, and wherein at least one sub-strand comprises a melting layer, and the object is a vehicle component selected from the group of:
i) vehicle interior component,
ii) heatable vehicle component,
iii) steering wheel,
iv) inflatable fluid-container, and
v) vehicle seat component wherein the electrical element and the object are connected to each other by ultrasonic welding.

54. The method according to claim 53, wherein the multifil conductor strand is one of a sensor strand, a shielding strand, and/or a heating strand.

55. A device produced by the method according to claim 53.
